(19) United States
(12) Patent Application Publication
(10) Pub. No.: US 2011/0180124 A1
(43) Pub. Date: Jul. 28, 2011

(54) PHOTOVOLTAIC CELL AND METHOD OF MANUFACTURING A PHOTOVOLTAIC CELL

(75) Inventors: Hanno Goldbach, Sevelen (CH); Tobias Roschek, Alt St. Johann (CH); Stefano Benagli, Neuchatel (CH); Bogdan Mereu, Chur (CH)

(73) Assignee: OERLIKON SOLAR AG, TRUEBBACH, Truebbach (CH)

(21) Appl. No.: 13/059,265

(22) PCT Filed: Jul. 8, 2009
(86) PCT No.: PCT/EP2009/058695

§ 371 Date: Apr. 6, 2011

Related U.S. Application Data
(60) Provisional application No. 61/089,934, filed on Aug. 19, 2008.

(51) Int. Cl. H01L 31/042; H01L 31/075; H01L 31/0224; H01L 31/20; H01L 31/0288; B82Y 99/00

(52) U.S. Cl. 136/244; 136/258; 136/256; 438/96; 977/755; 257/E31.014

(57) ABSTRACT

A photovoltaic cell comprises an electrode layer (1_{b}) of a transparent, electrically conductive oxide which is deposited upon a transparent carrier substrate (7_{b}). There follows a contact layer (11_{b}) which is of first type doped amorphous silicon and has a thickness of at most 10 nm. There follows a layer (26) of first type doped amorphous silicon compound which has a bandgap which is larger than the bandgap of the material of the addressed contact layer (11_{b}). Subsequently to the first type doped amorphous silicon compound layer (2_{b}) there follows a layer of intrinsic type silicon compound (3_{b}) and a layer of second type doped silicon compound (5_{b}).

The present invention is directed on a photovoltaic cell as well as on a method of manufacturing same.

Photovoltaic solar energy conversion offers the perspective to provide for an environmentally friendly means to generate electricity. However, at the present state, electric energy provided by photovoltaic energy conversion units is still significantly more expensive than electricity provided by conventional power stations. Therefore, the development of more cost-effective means of producing photovoltaic energy conversion units attracted attention in the recent years. Amongst different approaches of producing low-cost solar cells, thin-film silicon solar cells combine several advantageous aspects: firstly, thin-film silicon cells can be prepared by known thin-film deposition techniques such as plasma enhanced chemical vapor deposition (PEVCD) and thus offer the perspective of synergies to reduce manufacturing costs by using experiences achieved in the past for example in the field of other thin-film deposition technologies such as from display manufacturing technology. Secondly, thin-film silicon solar cells can achieve high energy conversion efficiencies striving for 10% and more. Thirdly, the main raw materials for the production of thin-film silicon-based solar cells are abundant and non-toxic.

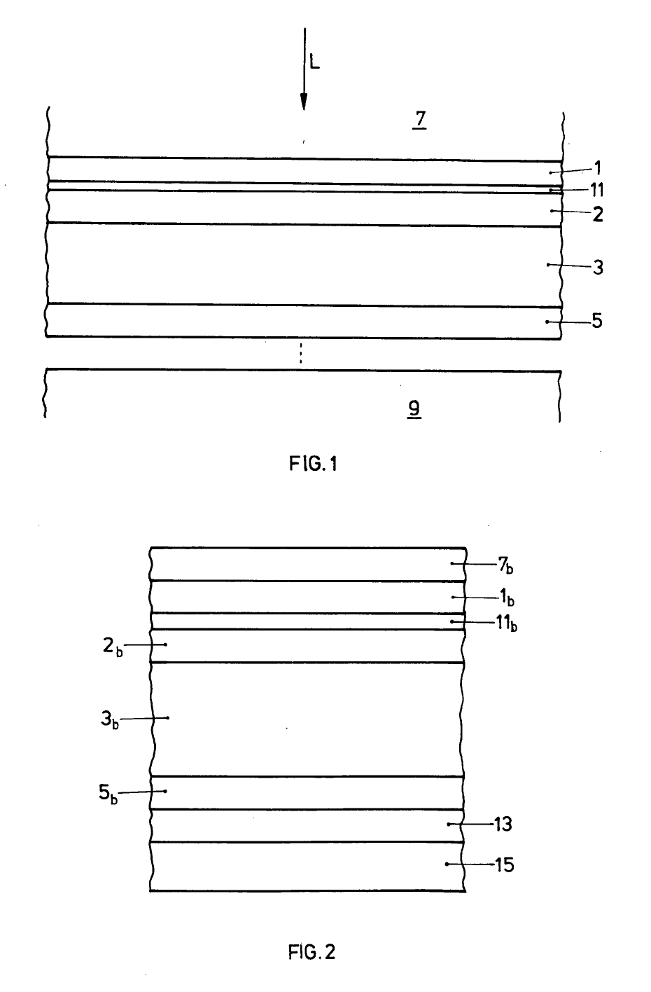

A thin-film solar cell subject to further development by the present invention and as generically known to the skilled artisan comprises as schematically shown in FIG. 1 and considered in direction of impinging light L an electrode layer 1 of a transparent, electrically conductive oxide (TCO). In the addressed direction L there follows a first active layer 2 of first-type doped silicon compound.

### Definition:

We understand under “type” of doping, positive -p- and negative -n- doping.

We further understand as a “silicon compound” a material which predominantly comprises silicon, but which additionally comprises one or more than one additional elements.

Subsequently to the addressed first active layer 2 there is provided a second active layer 3 which occupies the predominant part of the thickness of the thin-film junction structure and which is predominantly responsible for photovoltaic conversion. This layer 3 is of intrinsic type and of a silicon compound.

### Definition:

We understand by the term “intrinsic type” material a material which is either undoped or only doped to a neglectable amount or which is both type doped in such a manner that the respective doping types mutually compensate.

Subsequent to the second active layer 3 which is also called in the subsequent description “i-layer” is followed in the addressed direction L, by a third active layer 5 which is of a second type doped silicon compound.

In dependency from the fact where with respect to the solar cell structure as shown in FIG. 1 the carrier substrate for the thin layers is provided, the respective sequence of layer deposition is selected. Thus and with an eye on FIG. 1 if there is provided as a carrier substrate, a glass substrate as shown at 7, deposition of the addressed layers is started by the electrode layer 1 of TCO. Nevertheless, it is also possible to deposit the layer structure of the solar cell upon e.g. a reflective metal substrate as shown in FIG. 1 by 9. Then the sequence of deposition of the addressed layers is inversed.

With an eye on the material structure of the addressed layers it is known to provide the second active layer 3, the i-layer, of amorphous or of microcrystalline (often also called nanocrystalline) structure.

### Definition:

We understand under a material of microcrystalline structure a material wherein 20% to 80% of the volume (both limits included) is crystalline. In opposition thereto we define a material as being of amorphous structure if less than 20% of its volume is crystalline.

Irrespective whether the second active layer 3, the i-layer, 3 is of amorphous or of microcrystalline structure, it is known to apply the first active layer 2 as an amorphous material layer.

The present invention is addressing solar cells at which the said first active layer of first-type doped silicon compound is of amorphous structure.

So as to avoid optical losses by respective absorption in the first active layer 2 facing the illumination side of the cell, typically a wide band gap material layer is applied. However, this increases electrical series resistance at the interface between the electrode layer 1, the TCO layer, and the addressed first-type doped first active layer 2. This is particularly true if ZnO is selected as material of the electrode layer 1. To remedy this effect it is known to apply a contact layer 11 between the first active layer 2 of the cell and the electrode layer 1. Thereby, the contact layer 11 is of microcrystalline silicon compound and is first-type doped.

Provision of such contact layer of microcrystalline first-type doped silicon compound may only be realized at a relatively low deposition rate and additionally requires more advanced equipment due to higher power density to be applied for such deposition. This results in increased equipment and thereby product costs. Furthermore, a deposition process for depositing a layer in microcrystalline structure is more difficult and critical to accurately control, especially if such layer is to be deposited over a large area. Apart from thickness uniformity and doping uniformity, additionally the distribution of crystallinity over the extent of such layer has to be reproducibly controlled. Low deposition rates limit a high manufacturing throughput. It must be kept in mind that for large volume industrial production in fact every second saved in deposition time directly adds to throughput and to the amount of power for manufacturing.

It is an object of the present invention to provide for a photovoltaic cell whereat, as was addressed, a contact layer 11 according to FIG. 1 is provided, but which is producible at significantly reduced overall costs compared with known photovoltaic cells as addressed.

Thus, a photovoltaic cell according to the present invention comprises:
an electrode layer of a transparent electrically conductive oxide on a transparent carrier substrate, subsequently
a contact layer of first-type doped silicon compound, subsequently
a first active layer of first-type doped, amorphous silicon compound, subsequently
a second active layer of intrinsic type silicon compound, subsequently
a third active layer of second-type doped silicon compound,
   wherein the contact layer is of amorphous silicon compound and is at most 10 nm thick, the material of the addressed contact layer having a band gap which is smaller than the band gap of the material of the first active layer.

The approach of providing the contact layer of amorphous material structure was discarded by the skilled artisan to now, because of the relatively high absorption of light by amorphous silicon compound material. According to the present invention this is taken into account by reducing such absorption losses to a minimum by applying the contact layer of a very small thickness, as addressed, of 10 nm at most.

Deposition of the contact layer according to the present invention may further be performed at a high deposition rate compared with deposition rates for microcrystalline silicon compound deposition. This lead to significantly improved throughput especially important in industrial manufacturing. Further, deposition of a contact layer according to the present invention can be executed at definitely lower power densities and thus with a substantially lower amount of power. Typically microcrystalline silicon layers are deposited at a power density of about 2 kW/m², compared to approx. 300 W/m² for amorphous layers. This not only leads to a substantial reduction in power consumption, but additionally to a more streamlined processing setup. As the first active layer of first-type silicon compound is of amorphous material structure, the processing equipment for depositing the contact layer according to the present invention and such first active layer may be tailored for application of power densities in the range of just hundreds of Watts per m².

Thus, at least for depositing these two layers the respective processing equipment may be tailored for relatively low power densities, avoiding equipment for applying power densities higher by about 1 decade as is necessary if, as customarily, the addressed contact layer is provided in microcrystalline structure.

Additionally, also gas flow is substantially reduced by applying the addressed contact layer in amorphous structure with respect to gas flowing time as well as to necessitated overall amount of gas. E.g. and if the silicon compound of the contact layer at least compensates hydrogenated silicon, the hydrogen flow amounts to about 10′000 sccm for first-type, as an example p-doped, microcrystalline hydrogenated silicon. For depositing such first-type doped contact layer as an amorphous material layer the gas flow necessitated is only about 500 sccm.

The fact that the contact layer as provided according to the present invention has a band gap which is smaller than the band gap of the first active, first-type doped layer implies that the top of the valance band in the contact layer material and thus at the interface to the material of the electrode layer is approached to the Fermi level in the material of the addressed electrode layer. Thereby, the energetic difference between electrons and holes at the interface between the addressed materials becomes smaller and which leads to an increase of recombination rate and thus to a reduction of the appearing electrical series resistance.

In one embodiment of the photovoltaic cell according to the present invention the second active layer, which is the i-layer, is of hydrogenated silicon material.

In a further embodiment the addressed second active layer is of amorphous silicon compound. In this embodiment not only the contact layer, the first active layer, but additionally the second active layer—the i-layer—is of amorphous material structure. Thereby, the advantages as addressed above with respect to reduced power density and reduced gas flow, especially if the second active layer is of hydrogenated silicon, may be further exploited. The processing equipment for depositing all the contact layer, the first and the second active layers, may be tailored for low-power densities and gas consumption for depositing the addressed three layers is significantly reduced as well.

In one embodiment of the photovoltaic cell according to the invention the electrode layer is of ZnO. On one hand this material has shown to be highly advantageous for the addressed electrode layer, but leads with respect to a contact layer of microcrystalline structure to a significant series resistance increase. By providing the contact layer according to the present invention it becomes possible on one hand to further exploit the advantages of ZnO electrode layer material and to nevertheless avoid a respectively high series resistance across the interface of the electrode layer material and the contact layer material.

In a further embodiment of the photovoltaic cell according to the invention the material of the first active layer comprises carbon with a first atomic percentage and the material of the contact layer comprises carbon with a second atomic percentage. The second percentage is thereby lower than the first percentage. Thereby, by respectively selecting the amount of carbon in the first active layer on one hand and in the contact layer on the other hand the band gaps of the materials of these two layers may be accurately staggered to fit with the material of the electrode layer as was addressed above.

In one embodiment of the photovoltaic cell according to the invention absorption losses in the contact layer are further minimized by selecting the thickness of the contact layer to be at most 3 nm. The present invention is further directed on a photovoltaic converter panel comprising at least one cell as was addressed.

The method of manufacturing the photovoltaic cell according to the present invention comprises depositing an electrode layer of a transparent electrically conductive oxide and in contact therewith
a contact layer of first-type doped silicon on a transparent carrier substrate, in contact therewith
a first active layer of first-type doped amorphous silicon compound, in contact therewith
a second active layer of intrinsic type silicon compound, in contact therewith
a third active layer of second-type doped silicon compound,
   thereby depositing the contact layer of amorphous material and with a thickness which is at most 10 nm and controlling the band gap of the material of the contact layer to be smaller than the band gap of the material of the first active layer.

In one embodiment of the method according to the present invention the band gap in the contact layer material as well as in the first active layer are controlled by respectively selecting the amounts of carbon in the materials of these layers.

In one embodiment of the method according to the invention the electrode layer is deposited of ZnO.

In one embodiment of the method according to the invention the contact layer is deposited with a thickness of at most 3 nm.

In one embodiment of the method according to the invention the second active layer is deposited of hydrogenated silicon, and still in a further embodiment the material of the second active layer is deposited in amorphous material structure.

The invention shall now be further exemplified by an example and with the help of figures.

The figures show:

FIG. 2 schematically, a photovoltaic cell as realized according to the present invention;

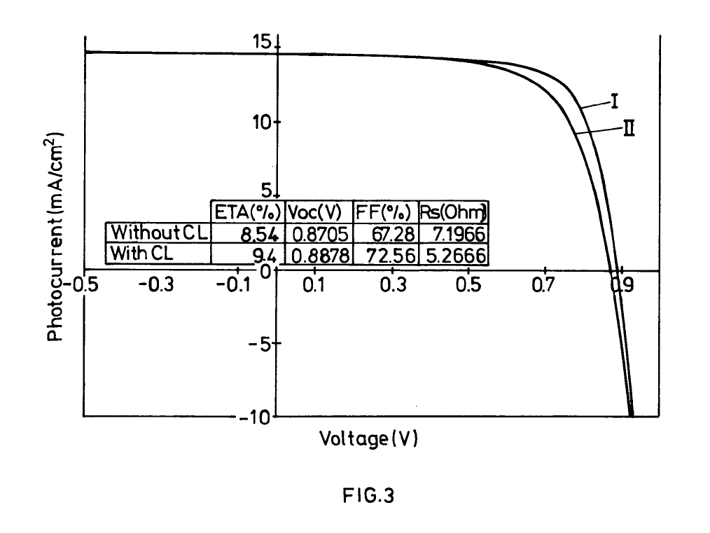

FIG. 3 the photocurrent vs. voltage characteristics of the cell according to FIG. 2 with inventively applied contact layer (I) and without applying such contact layer (II).

According to FIG. 2 there was deposited on a glass substrate 7_{b} an electrode layer 1_{b} of ZnO. On the electrode layer 1_{b} there was deposited a contact layer 11_{b} of amorphous hydrogenated silicon. The addressed contact layer 11_{b} was p-doped.

Subsequently, the first active layer 2_{b} was deposited of amorphous p-doped SiC. Subsequently, as a second active layer 3_{b}, an amorphous layer of hydrogenated silicon was deposited, followed by the third active layer 5_{b} of n-type doped amorphous hydrogenated silicon. Then second electrode layer 13 of n-doped ZnO and a wide-band metal reflector layer 15 was deposited. The contact layer was of 2 nm.

In FIG. 3 there is shown the characteristic of the photovoltaic cell according to the present invention and as exemplified by FIG. 2 by the course I, whereas, by course II, there is shown the characteristic of a photovoltaic cell identical and identically manufactured as that of FIG. 2, but without contact layer 11_{b}.

It may be seen that by applying the thin contact layer 7_{b} of amorphous hydrogenated silicon, whereas the band gap was reduced with respect to the band gap in the first active layer of p-doped amorphous SiC by respectively selecting the C content in the material of the two layers, the efficiency (ETA) was risen from 8.54 to 9.4%, the open loop voltage V_{oc} was risen from 0.8705 to 0.8878 V, the fill factor from 67.28 to 72.56, whereas the series resistance of the cell was reduced from 7.1966Ω to 5.2666Ω.

Thereby, it may be considered to reduce the thickness of the first active layer 2_{b} when applying the contact layer 11_{b} thereby maintaining the overall performance of the cell.

It must be emphasized that the photovoltaic cell as was exemplified and discussed may be one cell of a more than one cell structure wherein e.g. there is provided in direction of impinging light L, following a cell with an amorphous material structure a further cell with e.g. a microcrystalline material second active layer as i-layer.

1. A photovoltaic cell comprising
an electrode layer of a transparent, electrically conductive oxide on a transparent carrier substrate, subsequently
a contact layer of first type doped silicon compound, subsequently
a first active layer of first type doped, amorphous silicon compound, subsequently
a second active layer of intrinsic type silicon compound, subsequently
a third active layer of second type doped silicon compound,
wherein said contact layer is of amorphous silicon compound and is at most 10 nm thick, the material of said contact layer having a bandgap smaller than the bandgap of the material of said first active layer.

2. The cell of claim 1, said second active layer being of hydrogenated silicon.

3. The cell of claim 1 or 2, said second active layer being of amorphous silicon compound.

4. The cell of one of claims 1 to 3, said electrode layer being of ZnO.

5. The cell of one of claims 1 to 4, the material of said first active layer comprising C with a first atomic percentage of C and the material of said contact layer comprising C with a second atomic percentage, said second percentage being lower than said first percentage up to vanishing.

6. The cell of claims 1 to 5, said contact layer being at most 3 nm thick.

7. A photovoltaic converter panel comprising at least one photovoltaic cell according to one of claims 1 to 6.

8. A method of manufacturing a photovoltaic cell comprising depositing
an electrode layer of a transparent electrically conductive oxide on a transparent carrier substrate, in contact therewith
a contact layer of first type doped silicon compound, in contact therewith
a first active layer of first type doped amorphous silicon compound, in contact therewith
a second active layer of intrinsic type silicon compound, in contact therewith
a third active layer of second type doped silicon compound,
thereby depositing said contact layer of amorphous material with a thickness which is at most 10 nm and controlling the bandgap of the material of said contact layer to be smaller than the bandgap of the material of said first active layer.

9. The method of claim 8, comprising controlling said bandgaps by respective amounts of carbon in said materials.

10. The method of one of claim 8 or 9 comprising depositing said electrode layer of ZnO.

11. The method of one of claims 8 to 10 comprising depositing said contact layer with a thickness of at most 3 nm.

12. The method of one of claims 8 to 11 comprising depositing said second active layer of hydrogenated silicon.

13. The method of one of claims 8 to 12 comprising depositing said second active layer of amorphous material.
